(19) United States
(12) Patent Application Publication
(10) Pub. No.: US 2014/0061683 A1
(43) Pub. Date: Mar. 6, 2014

(54) LIGHT EMITTING DIODE PACKAGE AND METHOD FOR MANUFCTURING THE SAME

(71) Applicant: ADVANCED OPTOELECTRONIC TECHNOLOGY, INC., Hsinchu Hsien (TW)

(72) Inventors: CHUNG-MIN CHANG, Hukou (TW); CHIEN-LIN CHANG-CHIEN, Hukou (TW); HSUEN-FENG HU, Hukou (TW)

(73) Assignee: ADVANCED OPTOELECTRONIC TECHNOLOGY, INC., Hsinchu Hsien (TW)

(21) Appl. No.: 13/897,454

(22) Filed: May 20, 2013

(30) Foreign Application Priority Data
Aug. 29, 2012 (CN) 2012103118307

(51) Int. Cl. H01L 33/52; H01L 33/58

(52) U.S. Cl. CPC H01L 33/52; H01L 33/58
USPC 257/88; 438/27

(57) ABSTRACT

An LED package includes a substrate, an LED chip mounted on the substrate, and a lens formed on the substrate and encapsulating the LED chip therein. The lens includes a top surface and a bottom surface connecting a bottom end of the top surface. The bottom surface is directly formed on the substrate. A tangent of the top surface extends through a joint of the top surface and the bottom surface to define a contacting angle between the tangent and a plumb line, and the contacting angle is not larger than 60 degrees.

### BACKGROUND

1. Technical Field

The present disclosure relates to semiconductor devices and, more particularly, to a light emitting diode (LED) package.

2. Description of Related Art

A method for manufacturing an LED package includes following steps: providing a substrate and an LED chip; mounting the LED chip on the substrate; providing a lens and glue and adhering the lens to the substrate by the glue to make the lens covering the LED chip. However, the refractive index of the glue is different from that of the lens. Light emitted from the LED chip is prone to be reflected back into an interior of the lens by the glue. Thus, a light extraction efficiency of the LED package is disadvantageously affected.

Accordingly, it is desirable to provide an LED package and a method for manufacturing the LED package which can overcome the described limitations.

### BRIEF DESCRIPTION OF THE DRAWINGS

FIG. 1 is a cross sectional view of an LED package of the present disclosure.

FIG. 2 is an isometric view of a substrate with second blocking members of the LED package of FIG. 1.

### DETAILED DESCRIPTION

Embodiments of an LED package and a method for manufacturing the LED package will now be described in detail below and with reference to the drawings.

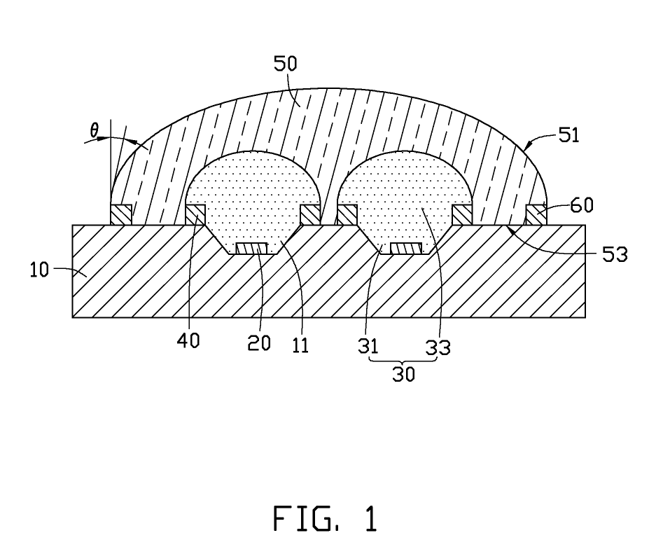

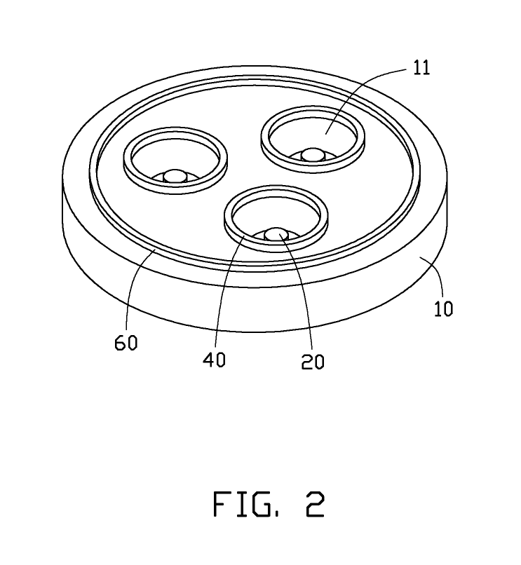

Referring to FIGS. 1-2, a method for manufacturing an LED package includes following steps:

The first step is providing a substrate 10, forming a circuit (not shown) on a top surface of the substrate 10, and defining receiving holes 11 in a top end of the substrate 10. In this embodiment, the substrate 10 is made of material having good heat dissipation performance and being electrically insulating, for example, ceramic. The receiving holes 11 are blind holes and spaced from each other. In this embodiment, three receiving holes 11 are defined in the substrate 10. Each receiving hole 11 has a trapeziform profile. A bore diameter of each receiving hole 11 decreases from top to bottom. An equilateral triangle is defined by lines formed by centers of the receiving holes 11 at a discretional plane parallel to the top surface of the substrate 10.

The second step is providing three LED chips 20, mounting the LED chips 20 in bottom ends of the receiving holes 11 and electrically connecting the circuit of the substrate 10. A height of each LED chip 20 is less than a depth of each receiving hole 11.

The third step is proving three second blocking members 40 and a first blocking member 60 and fixing the second blocking member 40 and the first blocking member 60 on the top surface of the substrate 10. The second blocking members 40 and the first blocking member 60 are protruded upwardly from the top surface of the substrate and made of hydrophobic material. The second blocking member 40 is annular and a bore diameter thereof is equal to the largest diameter of the receiving hole 11. Each second blocking member 40 is aligned with a top end of a corresponding receiving hole 11 of the substrate 10. The first blocking member 60 is annular and encloses the second blocking member 40 in a central thereof. A height of the second blocking member 40 is equal to that of the first blocking member 60 and less than 150 microns. Alternatively, the second blocking members 40 and the first blocking member 60 may be rectangular, trigonal or another required shaped.

The fourth step is providing glue and dispensing the glue in the receiving holes 11, an inside of the second blocking members 40 and an inside of the first blocking member 60 to encapsulate the LED chips 20 therein. The glue is a pure optical encapsulant material or a mixture mixed by a pure optical encapsulant material and phosphor powder. The glue fills in the receiving holes 11 and the first blocking member 60 and encapsulates the second blocking members 40 therein.

The fifth step is heating the glue to obtain three packaging layers 30 and a lens 50 enclosing the packaging layers 30 therein. The packaging layer 30 includes a bottom portion 31 filled in the receiving hole 11 to enclose the LED chip 20 therein and a top portion 33 protruding upwardly from the bottom portion 31. The top portion 33 is beyond the top surface of the substrate 10 and a bottom end thereof is enclosed by the second blocking member 40. The top portion 33 is hemispherical and a periphery of the bottom end thereof contacts an inner surface of the first blocking member 60. The lens 50 is hemispherical and a bottom end thereof is received in the first blocking member 60. A periphery of the bottom end of the lens 50 contacts an inner surface of the first blocking member 60. The lens 50 includes a top surface 51 and a bottom surface 53 connecting a bottom end of the top surface 51. In this embodiment, the top surface 51 is convex and the bottom surface 53 is plane. The bottom surface 53 is directly formed on the top surface of the substrate 10. A tangent of the top surface 51 extends through a joint of the top surface 51 and the bottom surface 53. A contacting angle θ is defined between the tangent and a plumb line. When the contacting angle θ is less, light reflected back into an interior of the lens 50 and the packaging layers 30 by the top surface 51 is less. If the contacting angle θ is less enough, a light extraction efficiency of the LED chip 20 is good. In this embodiment, the contacting angle θ is not larger than 60 degrees.

In this disclosure, the lens 50 is formed on the substrate 10 directly, so the glue is not need to be distributed between the lens 50 and the substrate 10 which reflects light back into the lens 50. Therefore, the light extraction efficiency of the LED chip 20 of the LED package is improved. Further, the lens 50 has a small contacting angle, a majority of light emitted from the LED chip 20 can radiates out from the top surface 51. Thus, the light extraction efficiency of the LED chip 20 of the LED package is improved.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. An LED package comprising:
a substrate;
an LED chip mounted on the substrate; and
a lens formed on the substrate and encapsulating the LED chip therein;
wherein the lens comprises a top surface and a bottom surface connecting a bottom end of the top surface, the bottom surface is directly formed on the substrate, a tangent of the top surface extends through a joint of the top surface and the bottom surface to define a contacting angle between the tangent and a plumb line, and the contacting angle is not larger than 60 degrees.

2. The LED package of claim 1, wherein the lens is hemispherical.

3. The LED package of claim 1 further comprising another two LED chips encapsulated by the lens on the substrate, wherein three receiving holes are defined in the substrate and are spaced from each other, and the LED chips are respectively received in the receiving holes.

4. The LED package of claim 3, wherein an equilateral triangle is defined by lines formed by centers of the receiving holes at a discretional plane parallel to a top surface of the substrate.

5. The LED package of claim 3, wherein each receiving hole has a trapeziform profile, and a bore diameter of each receiving hole decreases from top to bottom.

6. The LED package of claim 5, wherein three packaging layers are received in the receiving holes to encapsulate the LED chips therein and enclosed by the lens.

7. The LED package of claim 6, wherein each packaging layer comprises a bottom portion filled in the receiving hole and a top portion protruding from the bottom portion and being beyond the substrate.

8. A method for manufacturing an LED package comprising following steps:
providing a substrate;
providing a first blocking member formed on a top surface of the substrate;
providing an LED chip and mounting the LED chip on the top surface of the substrate, and the LED chip enclosed by the first blocking member;
providing glue and dispensing the glue in the first blocking member and to make the glue encapsulate the LED chip; and
heating the glue to obtain a lens formed on the substrate directly;
wherein the lens comprises a top surface and a bottom surface connecting a bottom end of the top surface, a tangent of the top surface extends through a joint of the top surface and the bottom surface to define a contacting angle between the tangent and a plumb line, and the contacting angle is not larger than 60 degrees.

9. The method of claim 8, wherein the top surface is convex and the bottom surface is plane.

10. The method of claim 8 further comprising a second blocking member formed on the top surface of the substrate and enclosed by the first blocking member, the LED chip located in the second blocking member, and glue received in the second blocking member being heated to obtain a packaging layer therein.

11. The method of claim 10, wherein the first blocking member and the second blocking member are protruded upwardly from the top surface of the substrate and made of hydrophobic material.

12. The method of claim 11, wherein a height of the first blocking member is equal that of the second blocking member.

13. The method of claim 12, wherein a height of the first blocking member is less than 150 microns.

14. The method of claim 10, wherein a receiving hole is defined in the substrate to receive the LED chip therein and the second blocking member is aligned with a top end of the receiving hole.

15. The method of claim 14, wherein the receiving hole has a trapeziform profile, and a bore diameter of each receiving hole decreases from top to bottom.

16. The method of claim 15, wherein a bore diameter of the second blocking member is equal to the largest diameter of the receiving hole.

17. The method of claim 10, wherein a height of each LED chip is less than a depth of each receiving hole.
